(19) United States
(12) Patent Application Publication
(10) Pub. No.: US 2019/0237644 A1
(43) Pub. Date: Aug. 1, 2019

(54) LIGHT EMITTING DEVICE WITH MULTI-LAYER ISOLATION STRUCTURE

(71) Applicant: MIKRO MESA TECHNOLOGY CO., LTD., APIA (WS)

(72) Inventor: Li-Yi CHEN, Tainan City (TW)

(21) Appl. No.: 15/884,321

(22) Filed: Jan. 30, 2018

(51) Int. Cl. H01L 33/60; H01L 33/62; H01L 25/075

(52) U.S. Cl. CPC H01L 33/60; H01L 2933/0058; H01L 25/0753; H01L 33/62

(57) ABSTRACT

A display device includes a substrate, a multi-layer isolation structure, and a plurality of light emitting device sets is provided. The multi-layer isolation structure is formed on the substrate. The multi-layer isolation structure includes a first isolation structure which is in contact with the substrate, and a second isolation structure which is above the first isolation structure. The first isolation structure and the second isolation structure have different reflectances. The plurality of light emitting device sets are present on the substrate. Each of the light emitting device sets includes at least one light emitting device, and the light emitting device sets are spaced apart from each other at least by the multi-layer isolation structure.

### BACKGROUND

### Field of Invention

The present disclosure relates to a light emitting device.

### Description of Related Art

The statements in this section merely provide background information related to the present disclosure and do not necessarily constitute prior art.

In recent years, micro light emitting devices have become popular in general and commercial lighting applications. As light sources, LEDs have many advantages including low energy consumption, long lifetime, small size, and fast switching, and hence conventional lighting, such as incandescent lighting, is gradually replaced by LED lights. These properties are promising for applications on displays.

### SUMMARY

According to some embodiments of the present disclosure, a display device is provided. The display device includes a substrate, a multi-layer isolation structure, and a plurality of light emitting device sets. The multi-layer isolation structure is formed on the substrate. The multi-layer isolation structure includes a first isolation structure which is in contact with the substrate, and a second isolation structure which is above the first isolation structure. The first isolation structure and the second isolation structure have different reflectances. The plurality of light emitting device sets are present on the substrate. Each of the light emitting device sets includes at least one light emitting device, and the light emitting device sets are spaced apart from each other at least by the multi-layer isolation structure.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1A is a schematic top view of a display device according to some embodiments of the present disclosure;

FIG. 1B is a schematic cross-sectional view of a display device according to some embodiments of the present disclosure;

FIG. 1C is a schematic cross-sectional view illustrating optical paths of a display device according to some embodiments of the present disclosure;

FIG. 1D is a schematic top view of a display device according to some embodiments of the present disclosure;

FIG. 2A is a schematic top view of a display device according to some embodiments of the present disclosure;

FIG. 2B is a schematic cross-sectional view of a display device according to some embodiments of the present disclosure;

FIG. 2C is a schematic top view of a display device according to some embodiments of the present disclosure;

FIG. 2D is a schematic cross-sectional view of a display device according to some embodiments of the present disclosure;

FIG. 3A is a schematic cross-sectional view of a display device according to some embodiments of the present disclosure;

FIG. 3B is a schematic cross-sectional view of a display device according to some embodiments of the present disclosure;

FIG. 3C is a schematic cross-sectional view of a display device according to some embodiments of the present disclosure;

FIG. 4A is a schematic cross-sectional view of a light emitting device according to some embodiments of the present disclosure;

FIG. 4B is a schematic cross-sectional view of a light emitting device according to some embodiments of the present disclosure; and

FIG. 4C is a schematic cross-sectional view of a light emitting device according to some embodiments of the present disclosure.

### DETAILED DESCRIPTION

Reference will now be made in detail to the present embodiments of the invention, examples of which are illustrated in the accompanying drawings.

Wherever possible, the same reference numbers are used in the drawings and the description to refer to the same or like parts.

In various embodiments, description is made with reference to figures. However, certain embodiments may be practiced without one or more of these specific details, or in combination with other known methods and configurations. In the following description, numerous specific details are set forth, such as specific configurations, dimensions and processes, etc., in order to provide a thorough understanding of the present invention. In other instances, well-known semiconductor processes and manufacturing techniques have not been described in particular detail in order to not unnecessarily obscure the present invention. Reference throughout this specification to “one embodiment,” “an embodiment” or the like means that a particular feature, structure, configuration, or characteristic described in connection with the embodiment is included in at least one embodiment of the invention. Thus, the appearances of the phrase “in one embodiment,” “in an embodiment” or the like in various places throughout this specification are not necessarily referring to the same embodiment of the invention. Furthermore, the particular features, structures, configurations, or characteristics may be combined in any suitable manner in one or more embodiments.

The terms “over,” “to,” “between” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

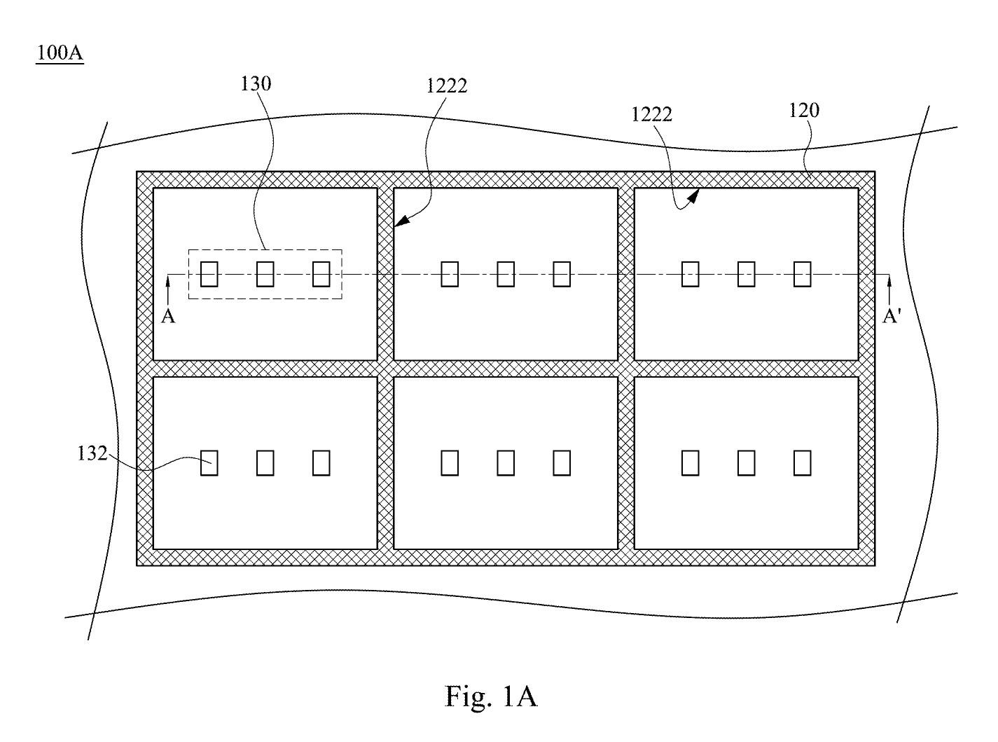

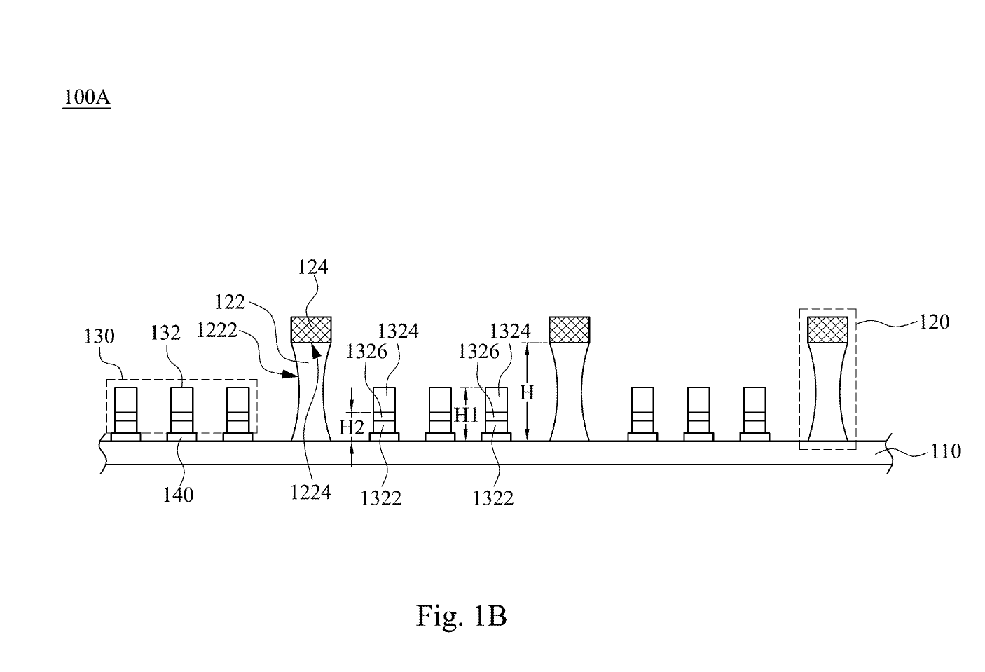

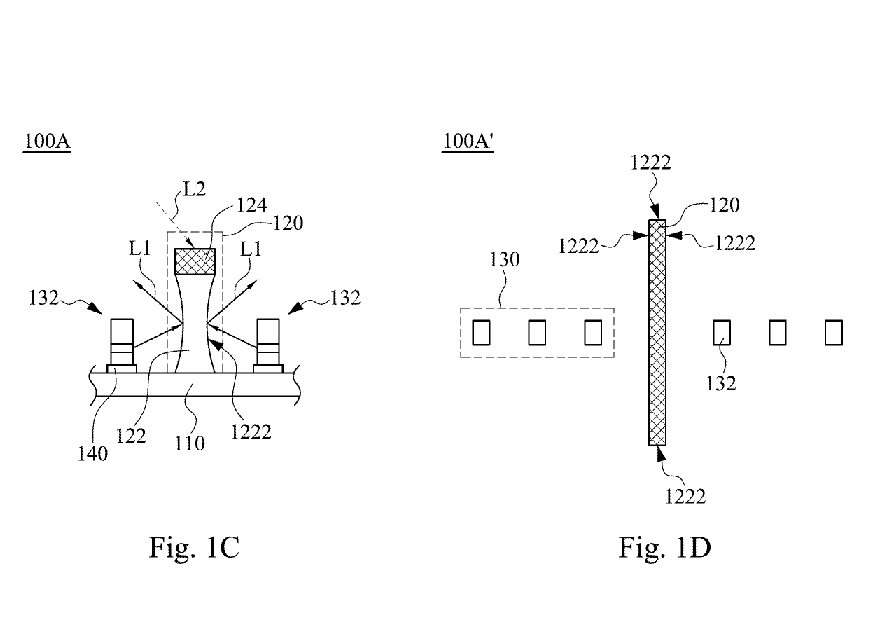

References are made to FIGS. 1A to 1D. FIG. 1A is a schematic top view of a display device 100A according to some embodiments of the present disclosure. FIG. 1B is a schematic cross-sectional view along A-A′ line of the display device 100A illustrated in FIG. 1A. FIG. 1C is a schematic cross-sectional view illustrating certain optical paths of a display device 100A emitting toward a multi-layer isolation structure 120 according to some embodiments of the present disclosure. FIG. 1D is a schematic top view of a display device 100A′ according to some embodiments of the present disclosure. According to some embodiments, a display device 100A including a substrate 110, the multi-layer isolation structure 120 and a plurality of light emitting device sets 130 is provided. The multi-layer isolation structure 120 is formed on the substrate 110. The multi-layer isolation structure 120 includes a first isolation structure 122 and a second isolation structure 124. The first isolation structure 122 is in contact with the substrate 110, and the second isolation structure 124 is present above the first isolation structure 122.

The plurality of light emitting device sets 130 are present on the substrate 110, and each of the light emitting device sets 130 includes at least one light emitting device 132. In some embodiments, the light emitting device sets 130 are spaced apart from each other at least by the multi-layer isolation structure 120.

Reference is made to FIG. 1C. FIG. 1C is a schematic cross-sectional view illustrating optical paths of a display device 100A according to some embodiments of the present disclosure. In some embodiments, the first isolation structure 122 and the second isolation structure 124 have different reflectances. For example, a reflectance of the first isolation structure 122 may be higher than a reflectance of the second isolation structure 124, so that the first isolation structure 122 tends to reflect lights, while the second isolation structure 124 tends to absorb lights, as shown in the schematic optical paths of FIG. 1C. Under this configuration, not only lights L1 emitted from the light emitting devices 132 may be reflected by the first isolation structure 122, but also light L2 from the environment will be absorbed by the second isolation structure 124. As a result, interference or crosstalk between lights emitted from different light emitting device sets 130 can be avoided, while the light extraction efficiency of the display device 100A can be improved.

Specifically, the multi-layer isolation structure 120 comprises resin, such as a photoresist, but should not be limited thereto. In some embodiments, the first isolation structure 122 may include TiO₂ particles or/and ZrO₂ particles, so as to increase the reflectance of the first isolation structure 122.

In some embodiments, a shape of a top surface 1224 of the first isolation structure 122 is defined by a vertical projection of the second isolation structure 124 on the top surface 1224 of the first isolation structure 122. Specifically, the multi-layer isolation structure 120 may be formed by photolithography, but should not be limited thereto. In some embodiments, a first resin layer is formed on the substrate 110, followed by the formation of a second resin layer above the first resin layer. The formations of the first resin layer and the second resin layer may be performed via spin-coating, slit-coating, or inkjet printing, but should not be limited thereto. After that, a pattern of desired multi-layer isolation structure 120 is projected on the second resin layer by exposure (e.g. UV light illumination) with a mask placed between a light source for exposure and the second resin layer. The mask has the pattern thereon.

After the exposure, the substrate 110 with the first resin layer and the exposed second resin layer on the first resin layer is developed in one process, developed in two processes, or developed and wet-etched in two processes to complete the formation of the multi-layer isolation structure 120.

Specifically, for the one process case, the exposed second resin layer and the first resin layer are developed with the exposed second resin layer as a mask for the first resin layer, such that a top surface of the first resin layer after said development is defined by a patterned second resin layer. Said patterned second resin layer is formed after the exposed second resin layer is developed. After the above process, the multi-layer isolation structure 120 composed of the patterned second resin layer and a patterned first resin layer is formed, wherein the patterned first resin layer is formed after said development.

For the two processes case, the exposed second resin layer is first developed so as to form a patterned second resin layer. After that, the patterned second resin layer acts as a mask for the first resin layer. Then the first resin layer is developed or wet etched to form a patterned first resin layer such that a top surface of the patterned first resin layer is defined by the patterned second resin layer. After the above processes, the multi-layer isolation structure 120 composed of the patterned second resin layer and the patterned first resin layer is formed.

The processes mentioned in the above embodiments help overcome the difficulty in developing the first resin layer due to high reflectance of the first resin layer. As a result, the first isolation structure 122 and the second isolation structure 124 can be formed in one development step, which simplifies the fabrication processes. In some embodiments, the first resin layer and the second resin layer are negative resists, such that the exposed portions remain and other portions are eliminated after development. In other embodiments, positive resists may be adopted, such that the exposed portions are eliminated and other portions remain after development.

In some embodiments, the first isolation structure 122 has a concave side surface 1222. The concave feature is due to development or wet etching process. The number of the concave side surface 1222 may be one or plurality. For example, in FIG. 1A, there are six concave side surfaces 1222 isolated from one another. The six concave side surfaces 1222 are inner side surfaces 1222 enclosing each of the light emitting device sets 130 respectively. In some other examples, there is only one concave side surface 1222 surrounding the isolation structure 120 since there is only one isolation structure 120 in a shape of a line, such as the example shown in FIG. 1D.

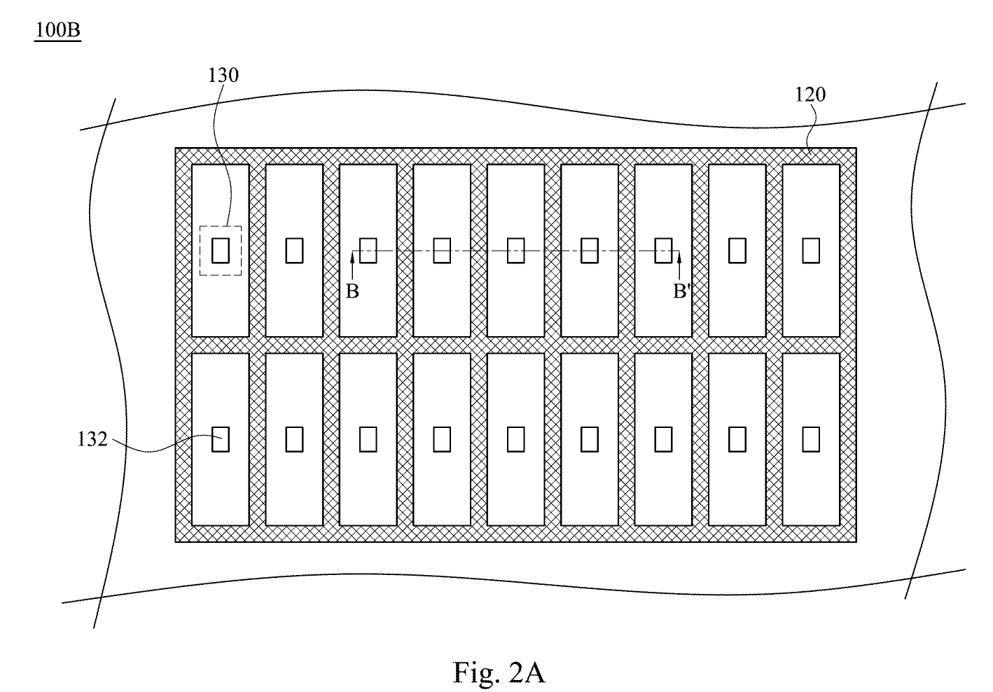

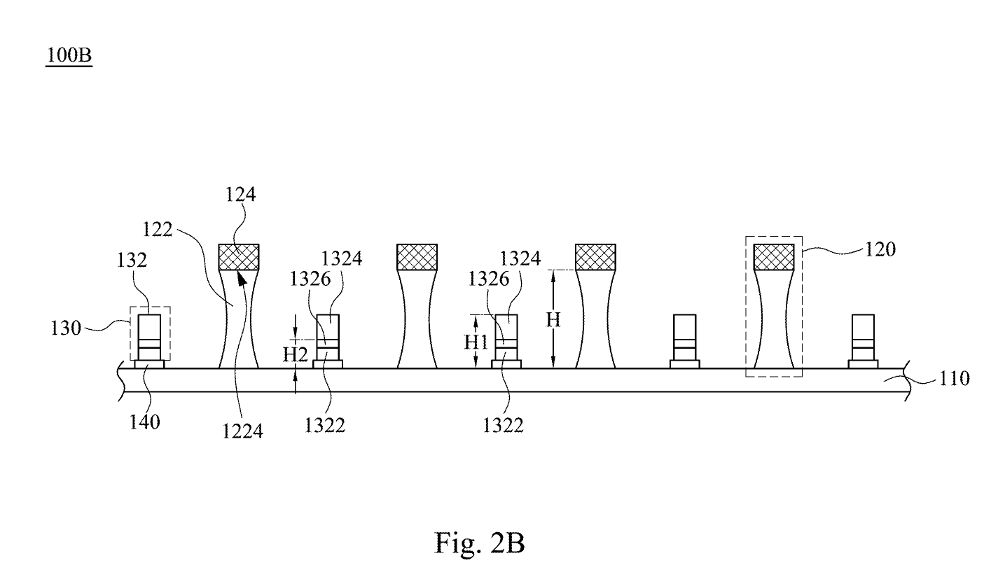

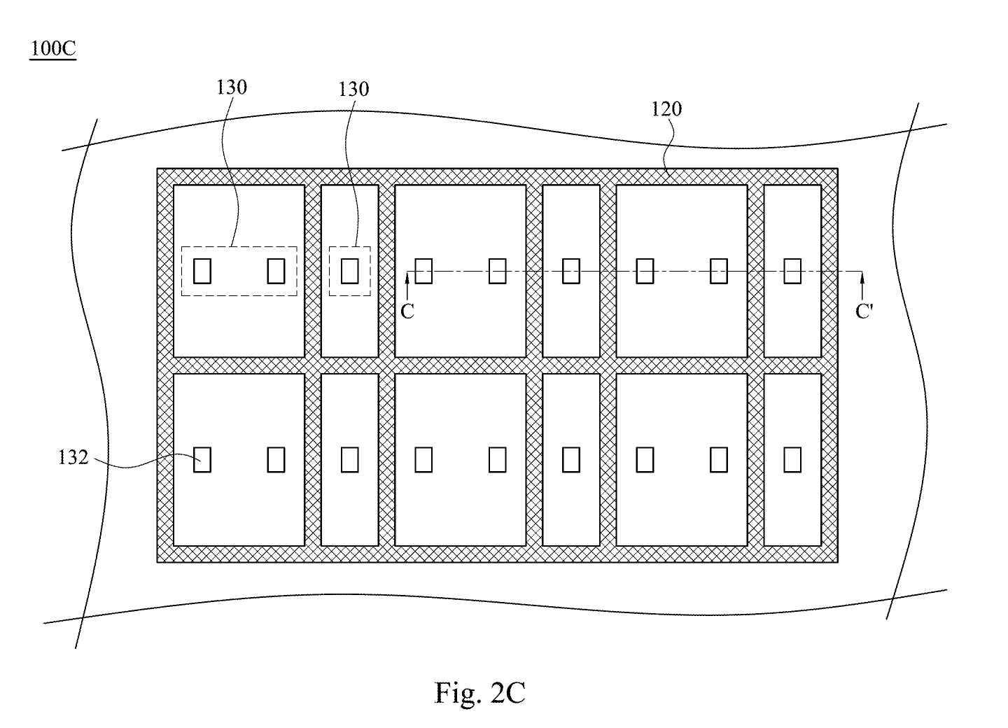

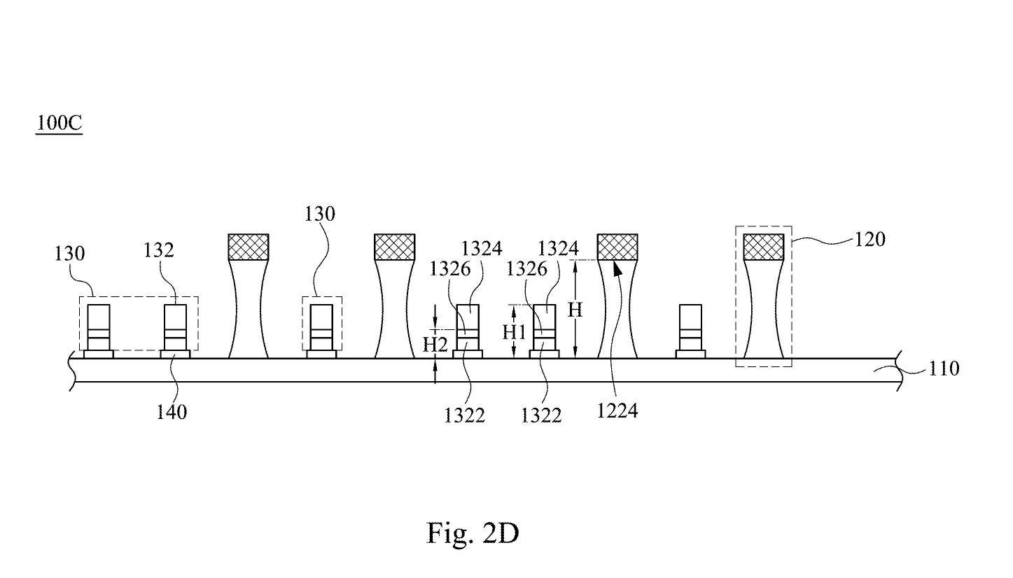

References are made to FIGS. 2A to 2D. FIG. 2A is a schematic top view of a display device 100B according to some embodiments of the present disclosure. FIG. 2B is a schematic cross-sectional view along B-B′ line of the display device 100B illustrated in FIG. 2A. FIG. 2C is a schematic top view of a display device 100C according to some embodiments of the present disclosure. FIG. 2D is a schematic cross-sectional view along C-C′ line of the display device 100C illustrated in FIG. 2A. The light emitting device sets 130 may include different number of light emitting devices 132. In some embodiments, each of the light emitting device sets 130 includes same number of the light emitting devices 132, such as three light emitting devices, as illustrated in FIGS. 1A and 1B. In other embodiments, each of the light emitting device sets 130 includes one light emitting device, as illustrated in FIGS. 2A and 2B. The light emitting device sets 130 in the same display device 100C as shown in FIGS. 2C and 2D may also include different number of light emitting devices 132. In some embodiments, at least one of the light emitting device sets 130 includes different number of the light emitting devices 132 from rest of the light emitting device sets 130. For example, as illustrated in FIGS. 2C and 2D, some light emitting device sets 130 include one light emitting device 132, and other light emitting device sets 130 include two light emitting devices 132. It should be noted that, the number of light emitting devices 132 in the light emitting device sets 130 should not be limited as described herein, and any combination of numbers is not departing from the present disclosure. Besides, each of the light emitting devices 132 in the same light emitting device set 130 may be equally spaced apart or unequally spaced apart. Furthermore, two of the light emitting devices 132 in the same light emitting device set 130 may belong to different types or the same type. Types of the light emitting devices 132 may be selected from, for instance, light emitting diodes (LEDs) of different emitting colors, such as red, green, blue, UV, or yellow, and should not be limited thereto.

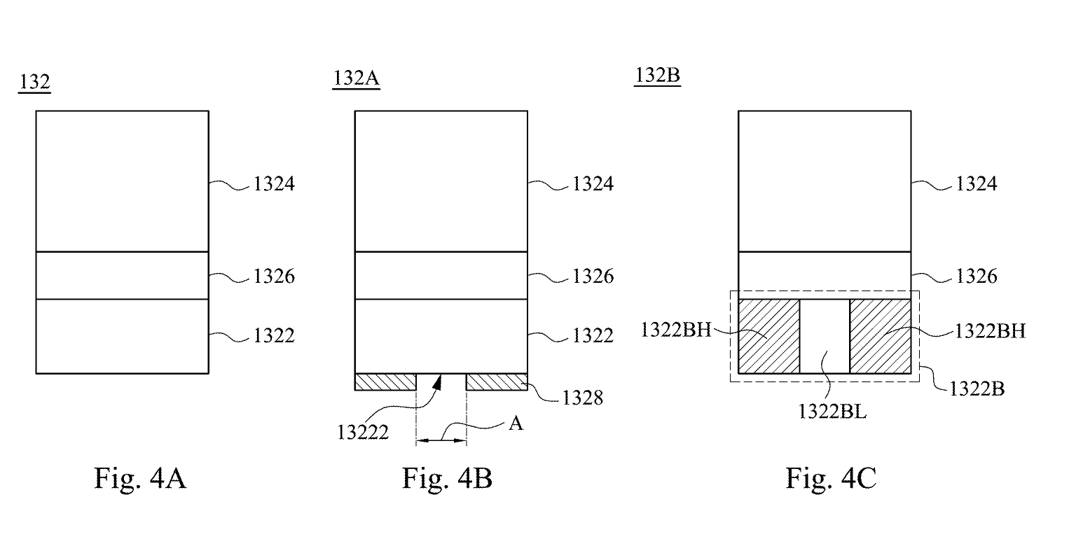

To effectively reflect lights emitted from the light emitting device sets 130, a height H of the first isolation structure 122 relative to the substrate 110 is greater than a height H1 of the light emitting devices 132 relative to the substrate 110. Specifically, in some embodiments, the light emitting devices 132 may include a first type semiconductor layer 1322, a second type semiconductor layer 1324, and a light emitting layer 1326. The configuration of the light emitting device 132 will be described in detail later with reference to FIGS. 4A to 4C. The second type semiconductor layer 1324 is above the first type semiconductor layer 1322. The light emitting layer 1326 is between the first type semiconductor layer 1322 and the second type semiconductor layer 1324. Thus, in some embodiments, the height H of the first isolation structure 122 relative to the substrate 110 is greater than a height H2 of the light emitting layer 1326 relative to the substrate 110. It should be noted that, in some embodiments, at least one of the light emitting devices 132 is electrically connected to the substrate 110 via a conductive pad 140, and the heights H1, H2 mentioned above should also include a height of the conductive pads 140.

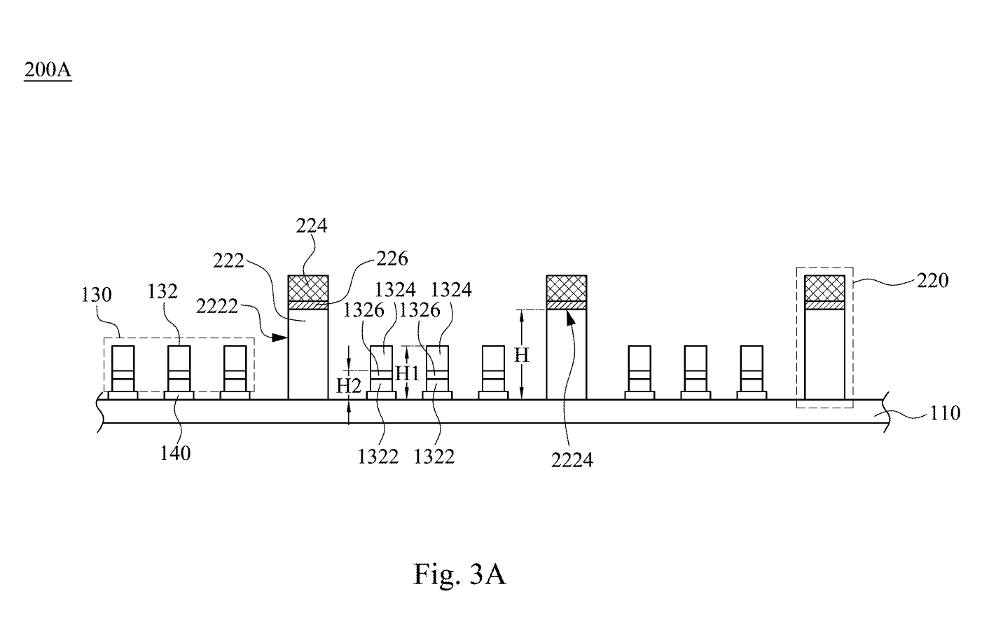

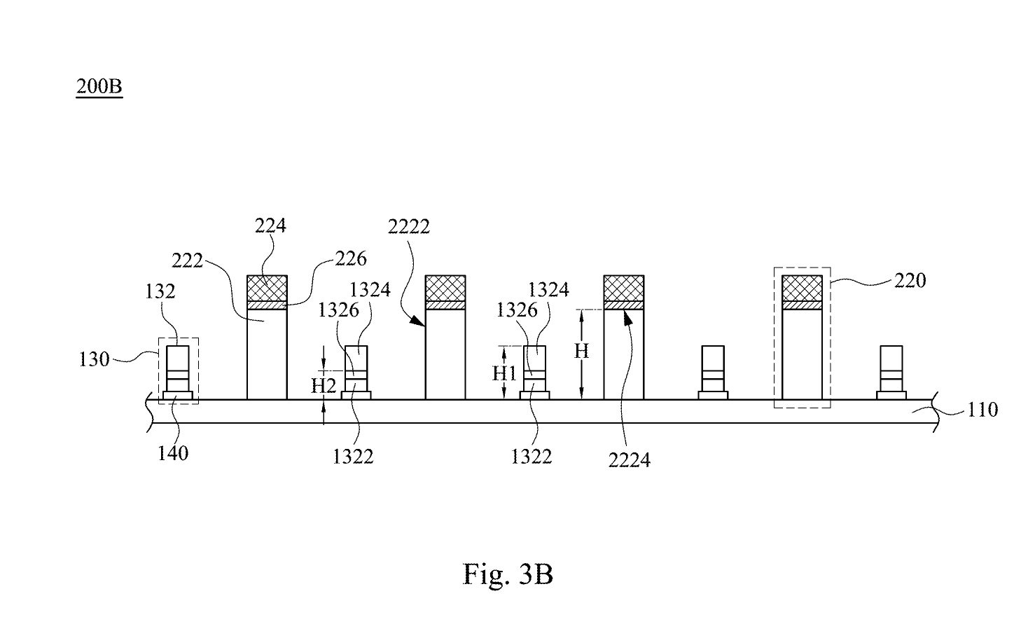

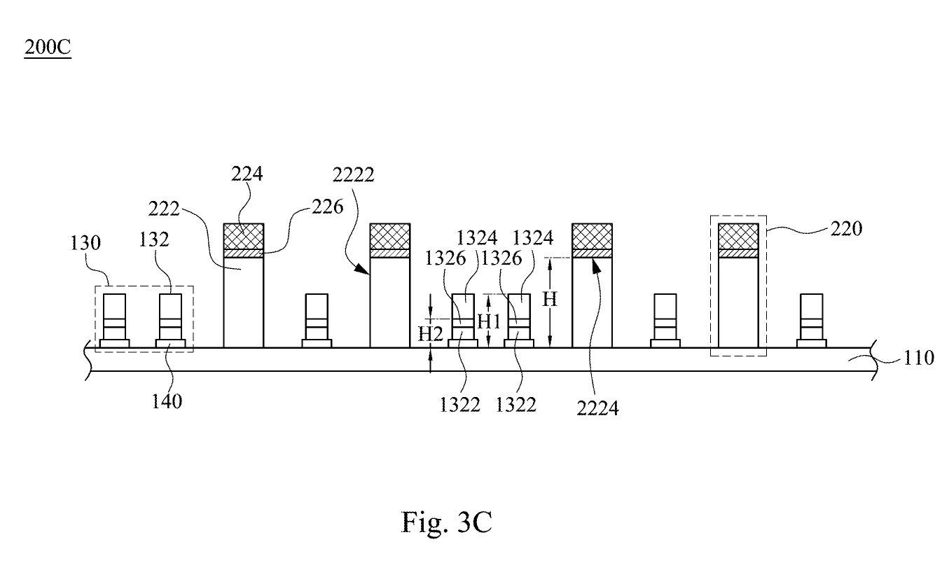

References are made to FIGS. 3A to 3C. FIGS. 3A, 3B and 3C are schematic cross-sectional views of display devices 200A, 200B, and 200C respectively according to some embodiments of the present disclosure. In some embodiments, a multi-layer isolation structure 220 further comprises a dielectric layer 226 present between a first isolation structure 222 and a second isolation structure 224 comparing to the multi-layer isolation structure 120. The dielectric layer 226 may be a SiO₂ layer or a SiNₓ layer, but should not be limited thereto. Under this configuration, the first isolation structure 222 may have a vertical side surface 2222 since a dry etching process may be used on the first isolation structure 222 to get the trilayer structure illustrated above. The dielectric layer 226 may be patterned by one of dry etching or wet etching, and the first isolation structure 222 is defined by a vertical projection of the dielectric layer 226 on a top surface 2224 of the first isolation structure 222. The whole processes are similar to that of fabricating the multi-layer isolation structure 120 and will not be repeated herein.

References are made to FIGS. 4A to 4C. FIGS. 4A, 4B, and 4C are schematic cross-sectional views of light emitting devices 132, 132A, and 132B respectively according to some embodiments of the present disclosure. In some embodiments, the light emitting device 132 may include the first type semiconductor layer 1322, the second type semiconductor layer 1324 present above the first type semiconductor layer 1322, and the light emitting layer 1326 present between the first type semiconductor layer 1322 and the second type semiconductor layer 1324, as exemplified in FIGS. 1A to 4A. In some other embodiments, a light emitting device 132A, in addition to the first type semiconductor layer 1322, the second type semiconductor layer 1324, and the light emitting layer 1326 as shown in the light emitting device 132, may also include a current control layer 1328 joined with the first type semiconductor layer 1322. The current control layer 1328 may present on a surface 13222 of the first type semiconductor layer 1322 as shown in FIG. 4B. The current control layer 1328 may also present within the first type semiconductor layer 1322 or on an interface between the light emitting layer 1326 and the first type semiconductor layer 1322. The current control layer 1328 may be a dielectric layer, so as to confine currents flowing through an area A, but should not be limited thereto. In still some other embodiments, a first type semiconductor layer 1322B in a light emitting device 132B may further include a low resistance portion 1322BL and a high resistance portion 1322BH comparing to the first type semiconductor layer 1322. There may be a plurality of low resistance portions 1322BL. A resistance may increase from the low resistance portion 1322BL toward the high resistance portion 1322BH. The difference on resistance between the low resistance portion 1322BL and the high resistance portion 1322BH may be performed by diffusion, or by doping from one side of the high resistance portion 1322BH. The diffusion may be performed by depositing a metal on the high resistance portion 1322BH and optionally heating. The metal may be Ti or Si, but should not be limited thereto.

In summary, the multi-layer isolation 120 structure including the first isolation structure 122 and the second isolation structure 124 having different reflectances reduces interference or crosstalk between lights emitted from different light emitting device sets, while improving the light extraction efficiency. The second isolation structure 124 of the multi-layer isolation structure 120 with lower reflectance can also absorb lights from the environment. In addition, the processes mentioned in some embodiments help overcome the difficulty in developing the resin layer with high reflectance. As a result, the first isolation structure 122 and the second isolation structure 124 can be formed in one development-step, which simplifies the fabrication processes.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

1. A display device, comprising:
a substrate;
a multi-layer isolation structure formed on the substrate, comprising:
a first isolation structure directly in contact with the substrate;
a second isolation structure above the first isolation structure, wherein the first isolation structure and the second isolation structure have different reflectances; and
a plurality of light emitting device sets present on the substrate, wherein each of the light emitting device sets comprises at least one light emitting device, and the light emitting device sets are spaced apart from each other at least by the multi-layer isolation structure.

2. The display device of claim 1, wherein the multi-layer isolation structure comprises resin.

3. The display device of claim 2, wherein the first isolation structure comprises TiO2 particles.

4. The display device of claim 2, wherein the first isolation structure comprises ZrO2 particles.

5. The display device of claim 2, wherein the first isolation structure has a concave side surface.

6. The display device of claim 1, wherein the multi-layer isolation structure further comprises a dielectric layer present between the first isolation structure and the second isolation structure.

7. The display device of claim 1, wherein the first isolation structure has a vertical side surface.

8. The display device of claim 1, wherein a shape of a top surface of the first isolation structure is defined by a vertical projection of the second isolation structure on the top surface of the first isolation structure.

9. The display device of claim 1, wherein a height of the first isolation structure relative to the substrate is greater than a height of the light emitting devices relative to the substrate.

10. The display device of claim 1, wherein the light emitting device comprises:
a first type semiconductor layer;
a second type semiconductor layer above the first type semiconductor layer; and
a light emitting layer between the first type semiconductor layer and the second type semiconductor layer.

11. The display device of claim 10, wherein a height of the first isolation structure relative to the substrate is greater than a height of the light emitting layer relative to the substrate.

12. The display device of claim 10, wherein the light emitting device further comprises a current control layer joined with the first type semiconductor layer.

13. The display device of claim 10, wherein the first type semiconductor layer comprises a low resistance portion and a high resistance portion, and a resistance increases from the low resistance portion toward the high resistance portion.

14. The display device of claim 1, wherein a reflectance of the first isolation structure is greater than a reflectance of the second isolation structure.

15. The display device of claim 1, wherein at least one of the light emitting device sets comprises different number of the light emitting devices from rest of the light emitting device sets.

16. The display device of claim 1, wherein each of the light emitting device sets comprises same number of the light emitting devices.

17. The display device of claim 1, wherein the display device further comprises a conductive pad present between one of the light emitting devices and the substrate.
